(19) United States
(12) Patent Application Publication
(10) Pub. No.: US 2009/0280637 A1
(43) Pub. Date: Nov. 12, 2009

(54) Method of manufacturing semiconductor device including ultra low dielectric constant layer

(75) Inventors: Kyoung-woo Lee, Suwon-si (KR); Hong-jae Shin, Seoul (KR); Jae-hak Kim, Seoul (KR); Jae-ouk Choo, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/453,326

(22) Filed: May 7, 2009

(30) Foreign Application Priority Data
May 7, 2008 (KR) 10-2008-0042451

(51) Int. Cl. H01L 21/768

(52) U.S. Cl. 438/618; 257/E21.585

(57) ABSTRACT

Provided is a method of manufacturing a semiconductor device. The method employs multi-step removal on a plurality of different porogens included in a low dielectric layer both before and after metal lines are formed, thereby facilitating formation of an ultra low dielectric constant layer which is used as an insulation layer between metal lines of a semiconductor device. The method may include forming an interlayer dielectric layer on a substrate, forming a plurality of porogens in the interlayer dielectric layer, removing a portion of the plurality of porogens in the interlayer dielectric layer to form a plurality of first pores in the interlayer dielectric layer, forming a wiring pattern where the plurality of first pores are formed, and removing the remaining porogens of the plurality of porogens to form a plurality of second pores in the interlayer dielectric layer.

### PRIORITY STATEMENT

This application claims priority under 35 U.S.C. §119 to Korean Patent Application No. 10-2008-0042451, filed on May 7, 2008, in the Korean Intellectual Property Office (KIPO), the entire contents of which are incorporated herein by reference.

### BACKGROUND

1. Field

Example embodiments relate to a method of manufacturing a semiconductor device including an ultra low dielectric constant layer with a low dielectric constant (k), and more particularly, to a method of manufacturing a semiconductor device including an ultra low dielectric constant layer for insulation of metal lines.

2. Description of the Related Art

In order to manufacture highly integrated semiconductor devices, a resistive capacitive (RC) delay is minimized or reduced, which is the product of capacitance C and resistance R of metal lines. For this minimization, a technology was developed which uses copper (Cu), having an electrical resistance lower than that of aluminum (Al), as a material for the lines, and which uses a material having a low dielectric constant as a material for an interlayer dielectric layer.

### SUMMARY

Example embodiments provide a method of manufacturing a semiconductor device, wherein the method may be employed to effectively form an ultra low dielectric constant layer which is used as an insulation layer between metal lines in a highly integrated semiconductor device. Example embodiments may prevent or reduce a coverage defect or a stress induction possibility that may occur in the metal lines, prevent or reduce signal cross-talk and improve signal transfer speed in highly integrated semiconductor devices having increased circuit density.

According to example embodiments, a method of manufacturing a semiconductor device may include may include forming an interlayer dielectric layer on a substrate, forming a plurality of porogens in the interlayer dielectric layer, removing a portion of the plurality of porogens in the interlayer dielectric layer to form a plurality of first pores in the interlayer dielectric layer, forming a wiring pattern where the plurality of first pores are formed, and removing the remaining porogens of the plurality of porogens to form a plurality of second pores in the interlayer dielectric layer.

Removing the portion of the plurality of porogens in the interlayer dielectric layer to form a plurality of first pores may include curing the interlayer dielectric layer at a first temperature, and removing the remaining porogens of the plurality of porogens to form a plurality of second pores may include curing the interlayer dielectric layer at a second temperature different from the first temperature. Forming the wiring pattern may further include partly etching the interlayer dielectric layer where the plurality of first pores are formed so as to form a cavity, and forming the wiring pattern in the cavity.

The interlayer dielectric layer may include a first porogen and a second porogen which have different decomposition temperature, respectively. The interlayer dielectric layer may be formed using a CVD (Chemical Vapor Deposition) process or a spin coating process. Forming the interlayer dielectric layer may further include coating a mixture on the substrate, wherein the mixture includes a precursor for forming the dielectric layer, a first porogen, and a second porogen. The mixture may be dissolved in an organic solvent so as to be coated on the substrate. The precursor may occupy about 50 to about 90% of a total weight of the mixture, the first porogen may occupy about 5 to about 45% of the total weight of the mixture, and the second porogen may occupy about 5 to about 45% of the total weight of the mixture.

The dielectric layer may be a low dielectric layer having a dielectric constant (k) lower than that of SiO₂. The first temperature may be equal to or higher than the decomposition temperature of the first porogen. The second temperature may be higher than the first temperature. The second temperature may be equal to or higher than the decomposition temperature of the second porogen. The second temperature may include a range of about 300 to about 500° C.

Curing the interlayer dielectric layer at either the first temperature or the second temperature may include applying one or two processes including heat treatment, UV (ultraviolet) radiation, and E-beam radiation to the interlayer dielectric layer. For example, the heat treatment and one of the UV radiation and the E-beam radiation may be simultaneously applied on the interlayer dielectric layer so as to perform the curing on the interlayer dielectric layer at either the first or second temperature.

The interlayer dielectric layer may have a first porosity of about 5 to about 40% of a total volume of the interlayer dielectric layer after the plurality of first pores are formed in the interlayer dielectric layer and prior to forming the wiring pattern, and the interlayer dielectric layer may have a second porosity greater than the first porosity after the plurality of second pores are formed in the interlayer dielectric layer. The second porosity may be about 25 to about 60% of the total volume of the interlayer dielectric layer.

Forming the wiring pattern may further include forming a metal layer in the cavity of the interlayer dielectric layer and on a top surface of the interlayer dielectric layer, and partially removing the metal layer until the top surface of the interlayer dielectric layer is exposed, thereby forming a metal line pattern in the cavity. The metal layer may be formed of a Cu or a Cu alloy.

### BRIEF DESCRIPTION OF THE DRAWINGS

Example embodiments will be more clearly understood from the following detailed description taken in conjunction with the accompanying drawings. FIGS. 1A-9 represent non-limiting, example embodiments as described herein.

FIGS. 1-8 are cross-sectional views illustrating a method of manufacturing a semiconductor device according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

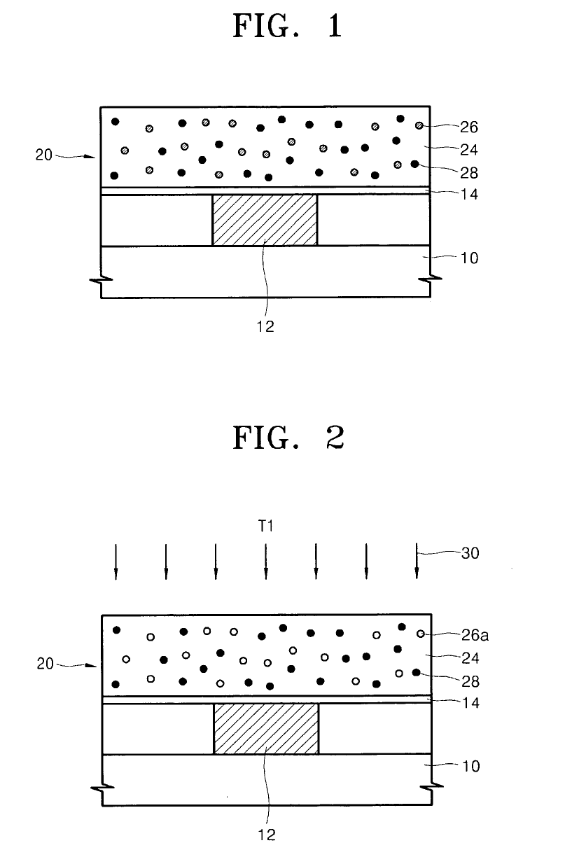

FIGS. 1-8 are cross-sectional views illustrating a method of manufacturing a semiconductor device according to example embodiments. FIGS. 1-8 are shown in the order of the manufacture process. Referring to FIG. 1, after an etch stop layer 14 is formed on a substrate 10, e.g., a semiconductor substrate, on which a conductive layer 12 is formed, an interlayer dielectric layer 20 may be formed on the etch stop layer 14. The interlayer dielectric layer 20 may include a plurality of pore generators (hereinafter, referred to as ‘porogens’) which are different from each other. For example, the interlayer dielectric layer 20 may be formed of a dielectric layer 24 and a plurality of porogens that are uniformly distributed in the dielectric layer 24 and have different decomposition temperatures. The plurality of porogens may include first porogens 26 and second porogens 28 which are different from each other. In FIG. 1, the interlayer dielectric layer 20 may include the first porogens 26 and the second porogens 28, but if required, the interlayer dielectric layer 20 may be formed to include three or more types of porogens. In the interlayer dielectric layer 20, the dielectric layer 24 may be an oxide layer or a nitride layer. For example, the dielectric layer 24 may be a low dielectric layer having a lower dielectric constant (k) than SiO₂.

For example, the dielectric layer 24 may be formed of SiO₂, boro-phospho-silicate glass (BPSG), phosphorus silicate glass (PSG), undoped silicate glass (USG), fluorinated silicate glass (FSG), SiOCH, amorphous carbon, or fluorinated amorphous carbon (FAC). Also, the dielectric layer 24 may be formed of hydrogen silsesquioxane (HSSQ), methyl silsesquioxane (MSSQ), cyclic silsesquioxane (CSSQ), aromatic polyimides, aromatic polycarbonate, PAE (poly(arylene ether)), cross-linked poly(phenylene), or cyclobutane derivatives.

Each of the plurality of porogens included in the interlayer dielectric layer 20 may be formed of branched poly(p-xylene), linear poly(p-phenylene), linear polybutadiene, branched polyethylene, poly(ethylene terephthalate) (PET), polyamide-6,6 (“Nylon 6/6”), syndiotactic polystyrene (PS-syn), polycaprolactone (PCL), poly(propylene oxide) (PPO), polycarbonates, poly(phenylene sulfide) (PPS), polyamideimide (PAI), polyphthalamide (“PPA”, “Amodel”), polymethylstyrene (PMS), polyetheretherketone (PEEK), poly(ether sulfone) (PES), poly(etherketone) (PEK), polyoxymethylene (POM), poly(butylene terephthalate) (PBT), polystyrene (PS), poly(norbornene), cetyltrimethylammonium bromide (CTAB), poly(ethylene oxide-b-propylene oxide-b-ethylene oxide (PEO-b-PPO-b-PEO), or cyclodextrin (CD).

The first porogens 26 and the second porogens 28 included in the interlayer dielectric layer 20 may be individually formed of different types of porogens which have different decomposition temperatures and which are selected from among the aforementioned porogens. Table 1 shows the decomposition temperature of representative porogens that may be included in the interlayer dielectric layer 20.

TABLE 1

| | Decomposition |
|---|---|
| | temperature |
| Porogens | (° C.) |
| branched poly(p-xylene) | 425-435 |
| linear poly(p-phenylene) | 420-430 |
| linear polybutadiene | 400-410 |
| branched polyethylene | 400-410 |
| PET | 300 |
| Nylon 6/6 | 302 |
| PS-syn | 320 |
| PCL | 325 |
| PPO | 325-375 |
| Polycarbonates | 325-375 |
| PPS | 332 |
| PAI | 343 |
| PPA, Amodel | 350 |
| PMS | 350-375 |
| PEEK | 399 |
| PES | 400 |
| PEK | 405 |
| POM | 280 |
| PBT | 260 |
| PS | 260 |

The first porogens 26 and the second porogens 28 may be selected in a manner such that a difference in decomposition temperatures between the first porogens 26 and the second porogens 28 may be greater than about 100° C. For example, PS having a relatively low decomposition temperature may be the first porogens 26, and linear polybutadiene having the relatively higher decomposition temperature may be the second porogens 28.

The interlayer dielectric layer 20 may be formed using a Chemical Vapor Deposition (CVD) process or a spin coating process. The interlayer dielectric layer 20 may be formed using a process in which a precursor for forming the dielectric layer 24 and the plurality of porogens are mixed in a predetermined or given weight ratio, and the mixture thereof may be dissolved in an organic solvent so as to coat the etch stop layer 14 on the substrate 10. For example, a mixture of the precursor for forming the dielectric layer 24, the first porogens 26, and the second porogens 28 may the precursor occupying about 50 to about 90% of a total weight of the mixture, the first porogens 26 occupying about 5 to about 45% of the total weight of the mixture, and the second porogens 28 occupying about 5 to about 45% of the total weight of the mixture. If required, the interlayer dielectric layer 20 may be planarized using a Chemical Mechanical Polishing (CMP) process.

Referring to FIG. 2, only some porogens of the plurality of porogens included in the interlayer dielectric layer 20 may be removed to form a plurality of first pores 26a in the interlayer dielectric layer 20. For example, as illustrated in FIG. 2, only the first porogens 26 from among the first and second porogens 26 and 28 may be removed to form the first pores 26a.

In order to remove the first porogens 26, a curing process 30 may be performed on the structure shown in FIG. 1 at a first temperature T1. The first temperature T1 may be a temperature that may selectively decompose only the first porogens 26 which decompose at a relatively low temperature. The curing process 30 may include performing heat treatment, ultraviolet (UV) radiation, and E-beam radiation on the structure shown in FIG. 1 at the first temperature T1. Where the UV radiation is performed as the curing process 30 at the first temperature T1, a broadband wavelength selected in the range of about 150 to about 400 nm may be used. Where the E-beam radiation is performed as the curing process 30 at the first temperature T1, a dose of about 50 to about 100 μC/cm² may be used. The curing processing 30 at the first temperature T1 may be performed in an inert gas environment for about 5 minutes to about 3 hours.

As a result of the curing process 30 at the first temperature T1, the first pores 26a may be formed in the interlayer dielectric layer 20 such that the interlayer dielectric layer 20 has a first porosity of about 5 to about 40% of a total volume of the interlayer dielectric layer 20, due to the first pores 26a formed in the interlayer dielectric layer 20. For example, a first porosity of the interlayer dielectric layer 20, which is obtained after the first pores 26a are formed therein, may be about 10 to about 20% of the total volume of the interlayer dielectric layer 20. In order to adjust the porosity of the interlayer dielectric layer 20 to a desired level due to the first pores 26a, the content of the first porogens 26, which are included in the interlayer dielectric layer 20 when the interlayer dielectric layer 20 is formed, may be adjusted.

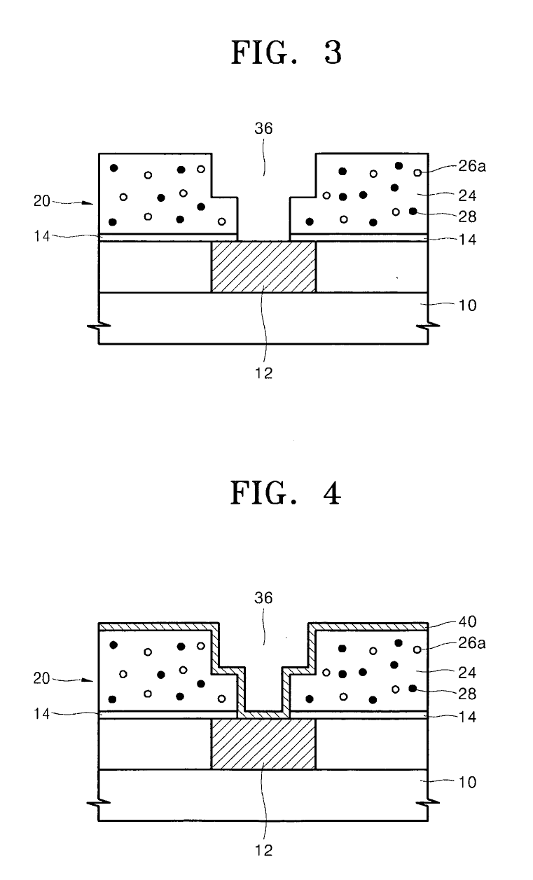

Referring to FIG. 3, the interlayer dielectric layer 20 may be partly etched to form a cavity 36 which has a dual damascene structure and which exposes the conductive layer 12. In order to form the cavity 36 in the interlayer dielectric layer 20, a hardmask (not shown), which partly covers a top surface of the interlayer dielectric layer 20, may be used as an etch mask, and then, the interlayer dielectric layer 20 may be etched using the etch stop layer 14 as an etch stop point. As illustrated in FIG. 3, the cavity 36 may be formed as a hole that penetrates through the interlayer dielectric layer 20. Otherwise, the cavity 36 may be formed as a trench (not shown) that has a depth lower than a thickness of the interlayer dielectric layer 20.

Referring to FIG. 4, a conductive barrier layer 40 may be formed on inner walls of the cavity 36, the top surface of the interlayer dielectric layer 20, and the top surface of the conductive layer 12. The conductive barrier layer 40 may be formed of one or more materials which are selected from the group including Ta, Ti, W, and nitrides thereof. For example, the conductive barrier layer 40 may be formed to have a stacked structure of Ta and TaN.

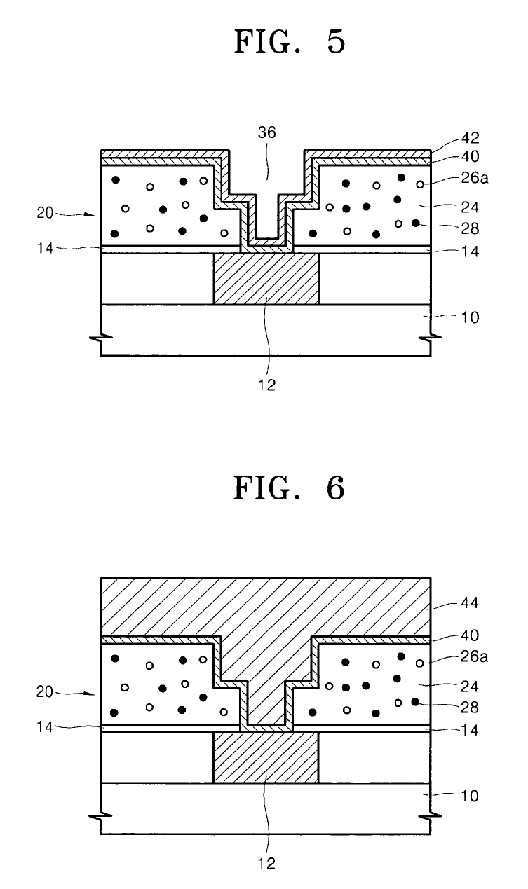

Referring to FIG. 5, a metal seed layer 42 may be formed on the conductive barrier layer 40. Where a Cu line or a Cu alloy line is formed, a Cu seed layer may be formed as the metal seed layer 42. Referring to FIG. 6, electroplating may be performed using the metal seed layer 42 so as to form a metal layer 44 from the metal seed layer 42. The metal layer 44 may be a Cu layer or a Cu alloy layer, and may be formed to have a thickness large enough to fill the cavity 36.

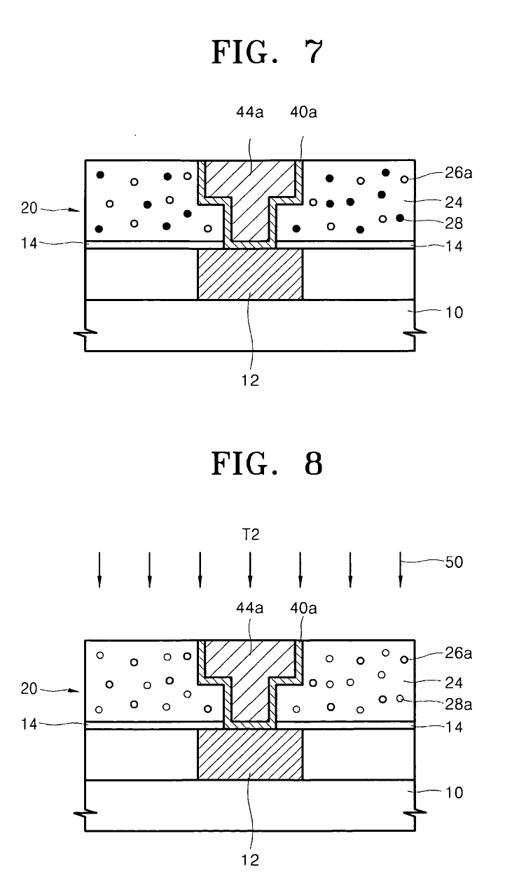

Referring to FIG. 7, the metal layer 44 and the conductive barrier layer 40 may be partly removed using the CMP process until the top surface of the interlayer dielectric layer 20 is exposed. As a result, a barrier pattern 40a and a metal line pattern 44a, which are formed of the remaining portions of the conductive barrier layer 40 and the metal layer 44, may remain in the cavity 36.

Referring to FIG. 8, the second porogens 28, which remain in the interlayer dielectric layer 20, may be removed to form a plurality of second pores 28a in the interlayer dielectric layer 20. In order to remove the second porogens 28, a curing process 50 may be performed on the structure shown in FIG. 7 at a second temperature T2 higher than the first temperature T1. The second temperature T2 may be higher than the decomposition temperature of the second porogens 28. For example, the second temperature T2 may be selected in the range of about 300 to about 500° C.

The curing process 50 may include performing heat treatment, UV radiation, and/or E-beam radiation on the structure shown in FIG. 7 at the second temperature T2. Where the UV radiation is performed as the curing process 50 at the second temperature T2, the broadband wavelength selected in the range of about 150 to about 400 nm may be used. Where the E-beam radiation is performed as the curing process 50 at the second temperature T2, the dose of about 50 to about 100 μC/cm2 may be used. The curing process 50 at the second temperature T2 may be performed in an inert gas environment for about 5 minutes to about 3 hours.

As a result of the curing process 50 at the second temperature T2, the second pores 28a may be formed in the interlayer dielectric layer 20, so that the interlayer dielectric layer 20 has a second porosity greater than the first porosity, due to the first pores 26a and the second pores 28a formed in the interlayer dielectric layer 20. For example, the interlayer dielectric layer 20 may have a second porosity of about 25 to about 60% of the total volume of the interlayer dielectric layer 20. For example, the second porosity of the interlayer dielectric layer 20, which is obtained after the first pores 26a and the second pores 28a are formed in the interlayer dielectric layer 20, may be about 25 to about 45% of the total volume of the interlayer dielectric layer 20. In order to adjust the porosity of the interlayer dielectric layer 20 to a desired level due to the first pores 26a and the second pores 28a, the content of the first and second porogens 26 and 28 may be adjusted which are included in the interlayer dielectric layer 20 when the interlayer dielectric layer 20 is formed.

As described above, the method of manufacturing the semiconductor device according to example embodiments may use the plurality of porogens, e.g., the first porogens 26 and the second porogens 28, which have different decomposition temperatures, to form the plurality of pores. The plurality of pores may include the first and second pores 26a and 28a in the interlayer dielectric layer 20, which is used as an interlayer dielectric layer between each of the metal lines. The method of example embodiments may be employed to form the interlayer dielectric layer 20 which is an ultra low dielectric constant layer. For example, the method of example embodiments may perform a multi-step removal of the plurality of porogens according to their different decomposition temperatures before and after the metal lines are formed, thereby forming the plurality of pores in the interlayer dielectric layer 20.

When the plurality of pores with a desired volume are formed at one time in the interlayer dielectric layer 20 before the metal lines are formed, and when the conductive barrier layer 40 is formed on the inner wall of the cavity 36 and the top surface of the interlayer dielectric layer 20 as described with reference to FIG. 4, the plurality of pores may be exposed on the inner wall of the cavity 36 and the top surface of the interlayer dielectric layer 20 due to the plurality of pores which are formed in the interlayer dielectric layer 20, resulting in an increase in the roughness of the inner wall and the top surface. In example embodiments, if the conductive barrier layer 40 is formed on the inner wall and the top surface, coverage characteristics may be undesirable.

However, in order to form the plurality of pores with the desired volume in the interlayer dielectric layer 20, the method according to example embodiments may employ the multi-step removal on the plurality of porogens according to their different decomposition temperatures before and after the metal lines are formed, thereby sequentially forming the plurality of pores. Only some pores, which are required to obtain a desired dielectric constant in the interlayer dielectric layer 20 prior to the forming of the conductive barrier layer 40 and the metal layer 44, may be formed in the cavity 36 of the interlayer dielectric layer 20, so that the conductive barrier layer 40 may be formed such that a surface roughness of the interlayer dielectric layer 20 is not substantially increased. Therefore, the coverage characteristic of the conductive barrier layer 40 and the metal layer 44, which are formed in the cavity 36 of the interlayer dielectric layer 20, may be improved.

Also, when all of the plurality of pores with the desired volume are formed at one time in the interlayer dielectric layer 20 after the metal lines are formed, the interlayer dielectric layer 20 may rapidly shrink due to abrupt formation of the plurality of pores in the interlayer dielectric layer 20, or stress may be caused in the interlayer dielectric layer 20 and surrounding layers making the structure defective. However, in order to form the plurality of pores with the desired volume in the interlayer dielectric layer 20, the method according to example embodiments may employ the multi-step removal on the plurality of porogens according to their different decomposition temperatures before and after the metal lines are formed, thereby sequentially forming the plurality of pores. Therefore, even though all of the plurality of porogens are removed from the interlayer dielectric layer 20 after the whole manufacture process has been completed, rapid shrinkage of the interlayer dielectric layer 20 due to an abrupt formation of all of the plurality of pores in the interlayer dielectric layer 20, or the related stress, may be prevented or reduced.

According to the method of manufacturing a semiconductor device according to example embodiments, in order to form the ultra low dielectric constant layer which is used as the insulation layer between each of the metal lines in an ultra highly integrated semiconductor device, the multi-step removal may be performed on the pore generators, that is, on the plurality of porogens in the low dielectric layer before and after the metal lines are formed, so that the plurality of pores may be formed in the low dielectric layer. Because the plurality of pores with the desired volume are formed in the low dielectric layer both before and after the metal lines are formed, a coverage defect occurring between the low dielectric layer and the metal lines, which penetrate through the low dielectric layer, may be prevented or reduced. Also, after the plurality of porogens are completely removed from the low dielectric layer, a stress induction possibility between the low dielectric layer and the metal lines, due to rapid shrinkage of the low dielectric layer because all of the plurality of pores are being formed in the low dielectric layer at one time, may be prevented or reduced. Thus, in the method of manufacturing a semiconductor device according to example embodiments, the coverage defect and the stress induction possibility that may occur in the metal lines may be prevented or reduced. In addition, forming the plurality of pores which provide air pores with a volume large enough to obtain the desired dielectric constant in the interlayer dielectric layer between each of the metal lines may enable effective formation of the ultra low dielectric constant layer for insulation between each of the metal lines.

While example embodiments have been particularly shown and described with reference to example embodiments thereof, it will be understood by those of ordinary skill in the art that various changes in form and details may be made therein without departing from the spirit and scope of the appended claims. Example embodiments should be considered in a descriptive sense only and not for purposes of limitation. Therefore, the scope of example embodiments is defined not by the detailed description but by the appended claims, and all differences within the scope will be construed as being included in example embodiments.

What is claimed is:

1. A method of manufacturing a semiconductor device, the method comprising:
forming an interlayer dielectric layer on a substrate;
forming a plurality of porogens in the interlayer dielectric layer;
removing a portion of the plurality of porogens in the interlayer dielectric layer to form a plurality of first pores in the interlayer dielectric layer;
forming a wiring pattern where the plurality of first pores are formed; and
removing the remaining porogens of the plurality of porogens to form a plurality of second pores in the interlayer dielectric layer.

2. The method of claim 1, wherein:
removing the portion of the plurality of porogens in the interlayer dielectric layer to form a plurality of first pores comprises curing the interlayer dielectric layer at a first temperature, and
removing the remaining porogens of the plurality of porogens to form a plurality of second pores comprises curing the interlayer dielectric layer at a second temperature different from the first temperature.

3. The method of claim 2, wherein forming the wiring pattern further comprises:
partly etching the interlayer dielectric layer where the plurality of first pores are formed so as to form a cavity; and
forming the wiring pattern in the cavity.

4. The method of claim 1, wherein the interlayer dielectric layer includes a first porogen and a second porogen which have different decomposition temperatures, respectively.

5. The method of claim 1, wherein the interlayer dielectric layer is formed using a CVD (Chemical Vapor Deposition) process.

6. The method of claim 1, wherein the interlayer dielectric layer is formed using a spin coating process.

7. The method of claim 1, wherein forming the interlayer dielectric layer further comprises:
coating a mixture on the substrate, wherein the mixture includes a precursor for forming the dielectric layer, a first porogen, and a second porogen.

8. The method of claim 6, wherein the mixture is dissolved in an organic solvent so as to be coated on the substrate.

9. The method of claim 6, wherein the precursor occupies about 50 to about 90% of a total weight of the mixture, the first porogen occupies about 5 to about 45% of the total weight of the mixture, and the second porogen occupies about 5 to about 45% of the total weight of the mixture.

10. The method of claim 1, wherein the dielectric layer is a low dielectric layer having a dielectric constant (k) lower than that of SiO₂.

11. The method of claim 4, wherein the first temperature is equal to or higher than the decomposition temperature of the first porogen.

12. The method of claim 4, wherein the second temperature is higher than the first temperature.

13. The method of claim 12, wherein the second temperature is equal to or higher than the decomposition temperature of the second porogen.

14. The method of claim 12, wherein the second temperature includes a range of about 300 to about 500° C.

15. The method of claim 2, wherein curing the interlayer dielectric layer at either the first temperature or the second temperature comprises applying one or two processes including heat treatment, UV (ultraviolet) radiation, and E-beam radiation to the interlayer dielectric layer.

16. The method of claim 15, wherein the heat treatment and one of the UV radiation and the E-beam radiation are simultaneously applied on the interlayer dielectric layer.

17. The method of claim 1, wherein:
the interlayer dielectric layer has a first porosity of about 5 to about 40% of a total volume of the interlayer dielectric layer after the plurality of first pores are formed in the interlayer dielectric layer and prior to forming the wiring pattern; and
the interlayer dielectric layer has a second porosity greater than the first porosity after the plurality of second pores are formed in the interlayer dielectric layer.

18. The method of claim 17, wherein the second porosity is about 25 to about 60% of the total volume of the interlayer dielectric layer.

19. The method of claim 3, wherein forming the wiring pattern further comprises:
forming a metal layer in the cavity of the interlayer dielectric layer and on a top surface of the interlayer dielectric layer; and
partially removing the metal layer until the top surface of the interlayer dielectric layer is exposed, thereby forming a metal line pattern in the cavity.

20. The method of claim 19, wherein the metal layer is formed of a Cu or a Cu alloy.
